(19) United States
(12) Patent Application Publication
(10) Pub. No.: US 2007/0200236 A1
(43) Pub. Date: Aug. 30, 2007

(54) Base semiconductor chip, semiconductor integrated circuit device, and semiconductor integrated circuit device manufacturing method

(76) Inventor: Yasuhiro Ishiyama, Shiga (JP)

Correspondence Address: MCDERMOTT WILL & EMERY LLP, 600 13TH STREET, NW, WASHINGTON, DC, 20005-3096, US

(21) Appl. No.: 11/651,526

(22) Filed: Jan. 10, 2007

(30) Foreign Application Priority Data
Jan. 27, 2006 (JP) 2006-019200
Nov. 15, 2006 (JP) 2006-308793

(51) Int. Cl. H01L 23/48

(52) U.S. Cl. 257/734

(57) ABSTRACT

A semiconductor integrated circuit device includes: a semiconductor substrate; a semiconductor chip including a plurality of functional blocks formed independently from each other in predetermined regions of the semiconductor substrate and each including a pad for transmitting a signal; and a plurality of inter-pad interconnects being connected to the pads and being capable of being cut. Signal transmission between the respective functional blocks is performed through the respective inter-pad interconnects.

### CROSS REFERENCE TO RELATED APPLICATIONS

This Non-provisional application claims priority under 35 U.S.C. §119(a) on Patent Application No. 2006-19200 filed in Japan on Jan. 27, 2006 and Patent Application No. 2006-308793 filed in Japan on Nov. 15, 2006, the entire contents of which are hereby incorporated by reference.

### BACKGROUND OF THE INVENTION

1. Field of the Invention

The present invention relates to a base semiconductor chip including a semiconductor substrate in which a plurality of functional blocks are formed, a semiconductor integrated circuit device using the base semiconductor chip, and a manufacturing method of the semiconductor integrated circuit device.

2. Background Art

One of semiconductor chips having complicated processing functions, there is known multi-chip modules (MCMs) in which a plurality of semiconductor chips including semiconductor integrated circuits formed therein are arranged on a die pad and are packaged (see, Japanese Patent Application Laid Open Publication No. 2000-349226A (FIG. 1), for example).

For MCMs, however, it is necessary to prepare a plurality of semiconductor chips having different functions, to determine the layout of the semiconductor chips on a die pad, and to interconnect the chips and the chips with the die pad by wires or the like. This complicates the manufacturing process, limits combinations of semiconductor chips, and so on.

To tackling the above problems, development of a system on chip (SOC) has advanced in which plural blocks of semiconductor integrated circuits are formed in a semiconductor substrate and the blocks are interconnected with each other (see Japanese Patent Application Laid Open Publication No. 2003-188351A (FIG. 1), for example).

In SOCs, a plurality of functional blocks having different functions, such as a microprocessor, a memory, and the like, are formed integrally with a single semiconductor substrate. Therefore, a large scale integrated circuit (LSI circuit) having a complicated processing function can be attained easily from a single chip without wiring each functional block.

In the LSI circuit of a conventional SOC, however, involves a problem first that fault analysis and the like are difficult. In general, an automatic replacement/routing tool for aiding layout of a SOC places each functional block in a semiconductor substrate at random. Further, the case may arise where an analysis is conducted in a section other than a layout section or another company, which involves difficulty in common information sharing therebetween. For this reason, the boundaries between the functional blocks become indefinite, and it is difficult to identify, upon occurrence of fault in an LSI circuit, which is a faulty functional block. Separation and division of an unnecessary functional block after manufacture is difficult, in addition.

Secondly, a plurality of functional blocks must be interconnected by forming a wiring layer on the semiconductor substrate only after a specification for interconnecting the functional blocks is determined, and therefore, it takes time from specification determination to product shipment.

Moreover, change in interconnection of the functional blocks, which can attain a SOC satisfying another specification, is almost impossible once the wiring layer is formed. SOCs are used usually for specialized purposes, and therefore, small-quantity and multi-product production of SOCs is demanded. As the diameters of semiconductor wafers are increased, however, a mass of SOCs are produced from a single semiconductor wafer, resulting in a stock pile of the SOCs.

Furthermore, when fault occurs in only one of a plurality of functional blocks, the SOC may be able to be used in a product in another specification which does not need the faulty functional block. Formation of the wiring layer, however, hinders the SOC from such diversion.

Usually, a plurality of functional blocks include a test functional block for performing a test, which is unnecessary after the test. It is difficult, however, to identify the test functional block, and the interconnected test functional block cannot be separated after the test.

### SUMMARY OF THE INVENTION

The present invention has its object of solving the above problems, namely, of providing a base semiconductor chip and a semiconductor integrated circuit device in which each functional block in a semiconductor substrate can be identified easily, in which the functional blocks can be divided selectively, and in which interconnection of the functional blocks can be recombined flexibly.

To accomplish the above object, a semiconductor integrated circuit device of the present invention is so composed that functional blocks formed in a base semiconductor chip are interconnected with each other by an interconnect capable of being cut.

Specifically, a semiconductor integrated circuit device according to the present invention includes: a semiconductor substrate; a semiconductor chip including a plurality of functional blocks formed independently from each other in predetermined regions of the semiconductor substrate and each including a pad for transmitting a signal; and a plurality of inter-pad interconnects being connected to the pads and being capable of being cut, wherein signal transmission between the respective functional blocks is performed through the respective inter-pad interconnects.

The semiconductor integrated circuit device of the present invention includes the semiconductor chip having the plurality of functional blocks each including the pad, which facilitates identification of each functional block. Accordingly, speedy fault analysis is enabled. The plurality of inter-pad interconnects which connect the pads and are capable of being cutting are provided, so that the functional blocks can be interconnected to each other after the semiconductor process, remarkably shortening a time period from determination of a specification for interconnection to product shipment. A combination of the functional blocks can be changed easily by changing a combination of interconnects interconnecting the pads. In consequence, plural kinds of semiconductor integrated circuits having different functions can be produced easily from a single base semiconductor chip, preventing stock from increasing.

In the semiconductor integrated circuit device of the present invention, the plurality of inter-pad interconnects preferably include at least one of a wire interconnect, a plated interconnect, and a layer interconnect, or includes any combination of the three. With this arrangement, the interconnection of the pads can be cut or recombined easily.

The semiconductor integrated circuit device of the present invention may further include an inter-block layer interconnect for interconnecting functional blocks directly, the inter-block layer interconnect being used for signal transmission between the interconnected functional blocks. With this arrangement, interconnects which would not be cut can be formed as an inter-block layer interconnect in advance, leading to an increase in productivity. In this case, also, each functional block in the semiconductor chip can be identified easily according to the pad provided in each functional block, involving no problems in cutting the inter-block layer interconnect.

In the semiconductor integrated circuit device of the present invention, preferably, some of the plurality of functional blocks serves as a test functional block for testing an operation of at least one of the other functional blocks, and an inter-pad interconnect connected to a pad of the test functional block is cut at the middle thereof. With this arrangement, the test functional block, which becomes unnecessary after a test, consumes no electric power, preventing power consumption from increasing.

In the semiconductor integrated circuit device of the present invention, preferably, some of the plurality of functional blocks is a surplus functional block which is not required to be operated, and the plurality of inter-pad interconnects are not connected to a pad formed at the surplus functional block out of the pads. Further, some of the plurality of functional blocks may be a surplus functional block which is not required to be operated, wherein an inter-pad interconnect connected to a pad formed at the surplus functional block out of the pads is cut in the middle thereof. With any of the above arrangements, an increase in power consumption by the unnecessary functional block is prevented. Further, if fault occurs in the unnecessary functional block, the chip becomes defective as a whole. With no such a functional block interconnected, such a disadvantage can be prevented, increasing the yield.

In the semiconductor integrated circuit device of the present invention, the semiconductor substrate is preferably in a polygonal shape in plan. With this arrangement, variation of semiconductor integrated circuit device increases.

A base semiconductor chip according to the present invention includes: a semiconductor substrate; and a plurality of functional blocks formed independently from each other in predetermined regions of the semiconductor substrate, wherein each of the functional blocks includes a pad for transmitting a signal.

In the base semiconductor chip of the present invention, each functional block includes the pad for inputting/outputting a signal to/from the corresponding functional block, so as to be identified easily. The functional blocks are formed independently from each other, so that cutting of the semiconductor substrate leads to easy physical separation of the functional blocks. This results in production of plural kinds of semiconductor integrated circuit devices having different functions from a single chip. Further, an increase in power consumption by an unnecessary functional block can be prevented.

In the base semiconductor chip of the present invention, a part of the semiconductor substrate where a region in which at least one functional block is formed is preferably cut out functions as an independent semiconductor chip. In this case, the semiconductor chip is preferably in a polygonal shape in plan.

The base semiconductor chip of the present invention may further includes an optional interconnect formed in a region between functional blocks of the semiconductor substrate for exchanging a function of a functional block by being cut. With this arrangement, a further larger number of kinds of semiconductor integrated circuit devices can be produced from a single semiconductor chip.

In the base semiconductor chip of the present invention, a trench may be formed in a boundary portion between functional blocks of the semiconductor substrate or a protrusion may be formed along a boundary therebetween.

Further, in a boundary potion between functional blocks of the semiconductor substrate, a guide pattern serving as a reference indicating the boundary portion may be provided. With any of the above arrangements, the boundary between the functional blocks becomes more definite. Further, the semiconductor substrate can be cut easily to suppress contamination of the base semiconductor chip in separating the functional blocks.

In this case, the guide pattern is preferably a guide line rendered along a boundary. Alternatively, the guide pattern may be provided a part slightly apart from a boundary between the functional blocks.

A method for manufacturing a semiconductor integrated circuit device according to the present invention includes the steps of: (a) preparing a base semiconductor chip, which is a semiconductor substrate in which a plurality of functional blocks each having a pad are formed independently from each other; (b) selectively combining the plurality of functional blocks by forming a plurality of inter-pad interconnects which connect corresponding pads out of the pads of the functional blocks and which are capable of being cut; and (c) separating some of the plurality of functional blocks by cutting some of the plurality of inter-pad interconnects. Accordingly, the semiconductor integrated circuit device can be easily manufactured which operates only a necessary functional block out of the plurality of functional blocks formed in the base semiconductor chip.

In the semiconductor integrated circuit device manufacturing method of the present invention, the plurality of inter-pad interconnects formed in the step (b) preferably include at least one of a wire interconnect, a plated interconnect, and a layer interconnect, or include any combination of the three.

The semiconductor integrated circuit device manufacturing method of the present invention may further includes a step (d) of testing, using some of the plurality of functional blocks, an operation of at least one of the other functional blocks before the step (c) and after the step (b), wherein the functional block used for the test is separated in the step (c). With the above arrangement, the test functional block can be separated after a test, preventing an increase in power consumption by the test functional block in the semiconductor integrated circuit device.

In the semiconductor integrated circuit device manufacturing method of the present invention, some of the plurality of functional blocks may be a surplus functional block which is not required to be operated, wherein the surplus functional block is separated in the step (c). With this arrangement, an increase in power consumption by the surplus functional block is prevented in the semiconductor integrated circuit device.

The semiconductor integrated circuit device manufacturing method of the present invention may further includes a step (e) of changing, after the step (c), a combination of the plurality of functional blocks by forming another wire interconnect or a plated interconnect. With this arrangement, the semiconductor circuit device can be recombined to a semiconductor circuit device having another function in the base semiconductor chip.

The semiconductor integrated circuit device manufacturing method of the present invention may further includes a step (f) of separating, after the step (a), a region of the semiconductor substrate where some of the plurality of functional blocks is formed from a region thereof where the other functional block is formed by dicing. With this arrangement, an unnecessary functional block can be separated physically.

In the semiconductor integrated circuit device manufacturing method of the present invention, at least one of the separated semiconductor substrates preferably has a polygonal shape in plan.

### BRIEF DESCRIPTION OF THE DRAWINGS

FIG. 1 shows a semiconductor integrated circuit device according to Embodiment 1 of the present invention, wherein FIG. 1A is a plan view and FIG. 1B is a sectional view taken along the line Ib-Ib in FIG. 1A.

FIG. 2 is a plan view showing a modified example of a semiconductor integrated circuit device according to Embodiment 1 of the present invention.

FIG. 3 shows another modified example of a semiconductor integrated circuit device according to Embodiment 1 of the present invention, wherein FIG. 3A is a plan view and FIG. 3B is a sectional view taken along the line IIIb-IIIb in FIG. 3A.

FIG. 4 is a plan view showing still another modified example of a semiconductor integrated circuit device according to Embodiment 1 of the present invention.

FIG. 5 shows yet another modified example of a semiconductor integrated circuit device according to Embodiment 1 of the present invention, wherein FIG. 5A is a plan view and FIG. 5B is a sectional view taken along the line Vb-Vb in FIG. 5A.

FIG. 6 shows still another modified example of a semiconductor integrated circuit device according to Embodiment 1 of the present invention, wherein FIG. 6A is a plan view and FIG. 6B is a sectional view taken along the line VIb-VIb in FIG. 6A.

FIG. 7 shows yet another modified example of a semiconductor integrated circuit device according to Embodiment 1 of the present invention, wherein FIG. 7A is a plan view and FIG. 7B is a sectional view taken along the line VIIb-VIIb in FIG. 7A.

FIG. 8 shows still another modified example of a semiconductor integrated circuit device according to Embodiment 1 of the present invention, wherein FIG. 8A is a plan view and FIG. 8B is a sectional view taken along the line VIIIb-VIIIb in FIG. 8A.

FIG. 9 is a plan view showing yet another modified example of a semiconductor integrated circuit device according to Embodiment 1 of the present invention.

FIG. 10 is a plan view showing a semiconductor chip according to Embodiment 2 of the present invention.

FIG. 11 is a plan view showing an example of division of the semiconductor chip according to Embodiment 2 of the present invention.

FIG. 12 is a plan view showing another example of division of the semiconductor chip according to Embodiment 2 of the present invention.

FIG. 13 shows a modified example of a semiconductor chip according to Embodiment 2 of the present invention, wherein FIG. 13A is a plan view and FIG. 13B is a sectional view taken along the line XIIIb-XIIIb in FIG. 13A.

FIG. 14 shows another modified example of a semiconductor chip according to Embodiment 2 of the present invention, wherein FIG. 14A is a plan view and FIG. 14B is a sectional view taken along the line XIVb-XIVb in FIG. 14A.

FIG. 15 is a plan view showing an example of division of the semiconductor chip according to Embodiment 2 of the present invention.

FIG. 16 is a plan view showing a modified example of a semiconductor chip according to Embodiment 2 of the present invention.

FIG. 17 is a plan view showing another modified example of a semiconductor chip according to Embodiment 2 of the present invention.

FIG. 18 is a plan view showing still another modified example of a semiconductor chip according to Embodiment 2 of the present invention.

FIG. 19 is a plan view showing yet another modified example of a semiconductor chip according to Embodiment 2 of the present invention.

### DESCRIPTION OF THE PREFERRED EMBODIMENTS

### Embodiment 1

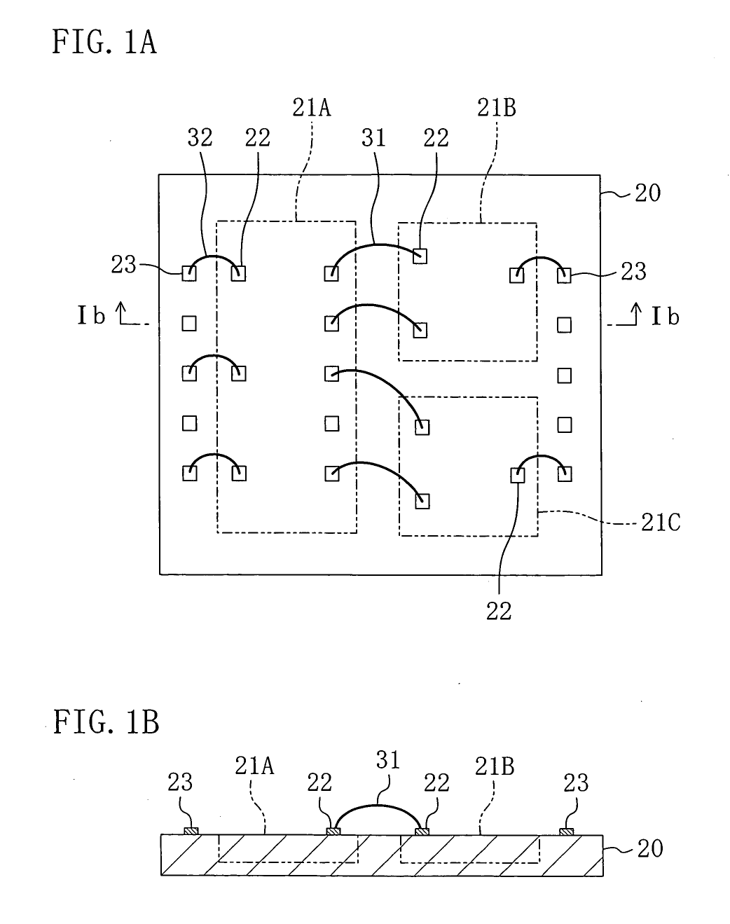

Embodiment 1 of the present invention will be described with reference to the drawings. FIG. 1 shows a main part of a semiconductor integrated circuit device (LSI circuit) according to Embodiment 1, wherein FIG. 1A is a plan view and FIG. 1B is a sectional view taken along the line Ib-Ib in FIG. 1A.

As shown in FIG. 1, the LSI circuit of the present embodiment includes a base semiconductor chip 20 as a semiconductor substrate in which a plurality of functional blocks as semiconductor integrated circuits are formed, and wire interconnects 31 for interconnecting the functional blocks. In FIG. 1, three functional blocks of a first functional block 21A, a second functional block 21B, and a third functional block 21C are provided, for example. Each functional block may be any functional block of, for example, a microprocessor, a memory, or the like.

The functional blocks are formed independently from each other in predetermined regions of the base semiconductor chip 20 so that only a necessary functional block is operated. Further, an unnecessary functional block can be separated from the base semiconductor chip 20 physically as needed.

In each functional block, there are provided input/output terminals (not shown) and a plurality of functional block pads 22 electrically connected to the input/output terminals. The input/output terminals input a signal from the outside to the corresponding functional block, output a signal to the outside from the corresponding functional block, or supply electric power to the corresponding functional block from the outside. Accordingly, input of a signal or power supply to the functional block pads 22 makes the corresponding functional blocks to output a signal therefrom or to be operated.

A plurality of external connection pads 23 are formed at the peripheral part of the base semiconductor chip 20. The external connection pads 23 can be connected to, for example, a lead frame (not shown) by means of a wire or be used for flip chip mounting.

Functional block pads 22 of correlated functional blocks are connected to each other electrically by means of a wire interconnect 31 as an inter-pad interconnect so that signal transmission is performed among the first functional block 21A, the second functional block 21B, and the third functional block 21C. Predetermined functional block pads 22 are connected to predetermined external connection pads 23 by means of wire interconnects 32 as inter-pad interconnects. Whereby, the first functional block 21A, the second functional block 21B, and the third functional block 21C transmit signals to and from the outside, thus realizing an LSI circuit exhibiting a predetermined function as a whole.

In the LSI circuit of the present embodiment, each functional block formed in the base semiconductor chip 20 is interconnected to each other electrically by means of the wire interconnects 31 with the functional block pads 22 interposed. The wire interconnects 31 can be formed in a period shorter than time required for forming a wiring layer. Accordingly, when the base semiconductor chip 20 having necessary functional blocks is formed by a semiconductor process in advance and each functional block is interconnected by the wire interconnects 31 after specification of interconnection is determined, a period between determination of a specification for interconnection and product shipment can be reduced remarkably.

Each functional block includes the functional block pads 22, which define the position of the corresponding functional block in the base semiconductor chip 20. Accordingly, upon occurrence of fault, the faulty functional block can be identified easily, leading to speedy fault analysis and the like.

Any arrangement of the functional block pads 22 facilitates identification of the corresponding functional block, but arrangement under a given rule promotes further easy identification thereof. FIG. 1 shows one example of the arrangement in which the functional block pads 22 are arranged along two sides of each functional block. Arrangement of the functional block pads 22 along at least one side thereof enables easy identification of the boundary between two functional blocks. The functional block pads 22 may be arranged along each side of the functional blocks or may be arranged at each corner or at diagonal two corners of the functional blocks according to the number of functional block pads 22.

In the LSI circuit of the present embodiment, each functional block includes a plurality of functional block pads 22, but some of the functional blocks may include only one functional block pad 22 as a power source pad, a test pad, or the like. In the functional block including only one functional block pad, arrangement of the functional block pad 22 at the center thereof defines the position of the corresponding functional block.

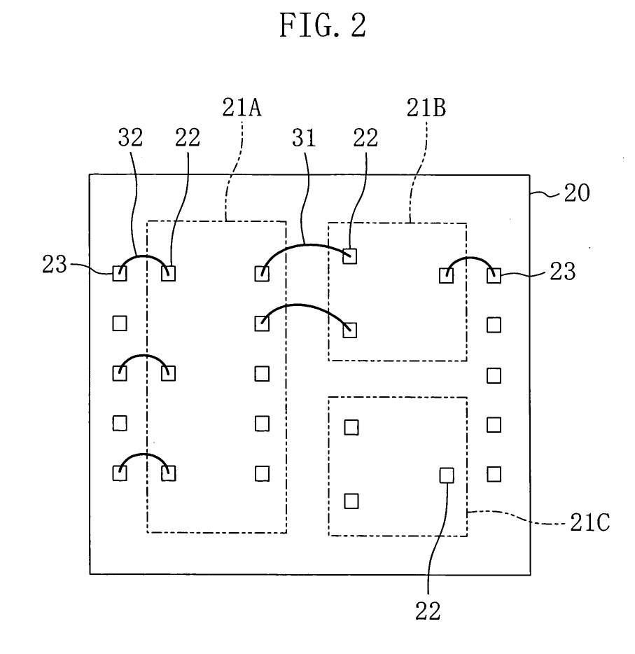

Employment of the wire interconnects 31 enables easy recombination of the functional blocks as needed. Accordingly, plural kinds of LSI circuits of which specifications are different can be obtained easily from a single base semiconductor chip 20. For example, as shown in FIG. 2, in the case where the third functional block 21C is unnecessary, the functional block pad 22 connected to the third functional block 21C is not connected to any other functional block pads 22 to separate the third functional block 21C. Separation of the third functional block 21C means no power supply to the third functional block 21C, obviating an increase in power consumption by the third functional block 21C in the LSI circuit.

The functional blocks once interconnected can be separated easily. For example, in the case where the third functional block 21C is used only for an operation test of the first functional block 21A, after the third functional block 21C is interconnected by a wire and a test is carried out, the wire interconnected to the third functional block 21C is cut to separate the third functional block 21C. This suppresses an increase in power consumption by the test functional block in the LSI circuit.

Since the functional blocks are formed independently from each other, an unnecessary functional block can be removed physically from the semiconductor chip.

When removed, an increase in area of the semiconductor chip by the unnecessary functional block can be prevented.

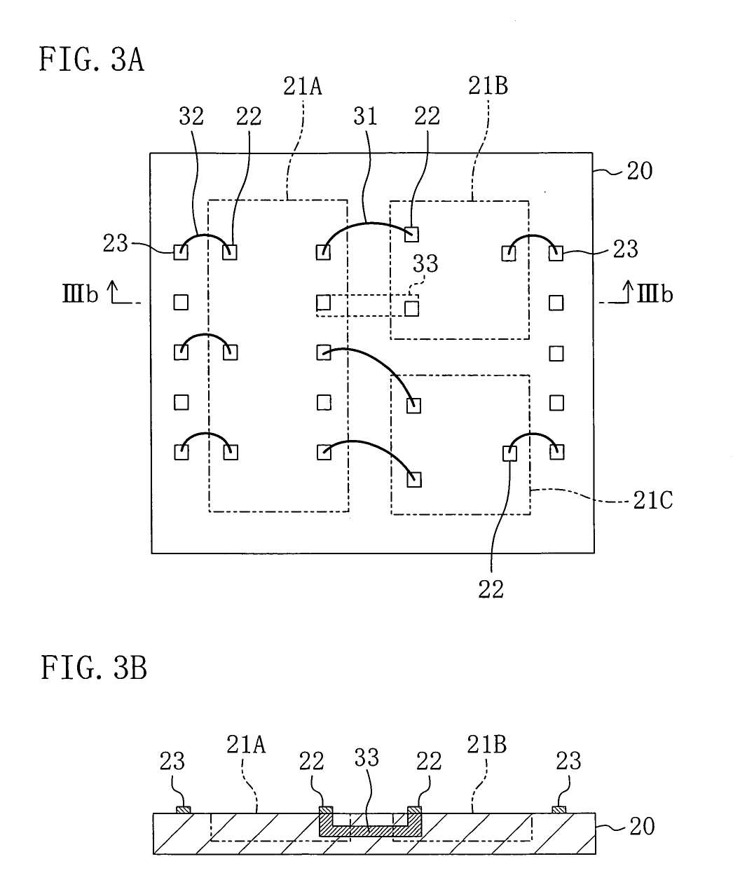

The above description refers to the case where all the inter-pad interconnects are wire interconnects, wherein the inter-pad interconnects are required only to be capable of being cut. For example, a layer interconnect 33 buried in a wiring layer formed on the semiconductor substrate may be employed in combination with the wire interconnects 31, as shown in FIG. 3. It is difficult in general to identify which part of layer interconnects interconnecting the elements should be cut, and therefore, the general layer interconnects once formed cannot be cut. In contrast, the layer interconnects 33 in the present embodiment connects the pads, and accordingly, a part to be cut can be identified easily.

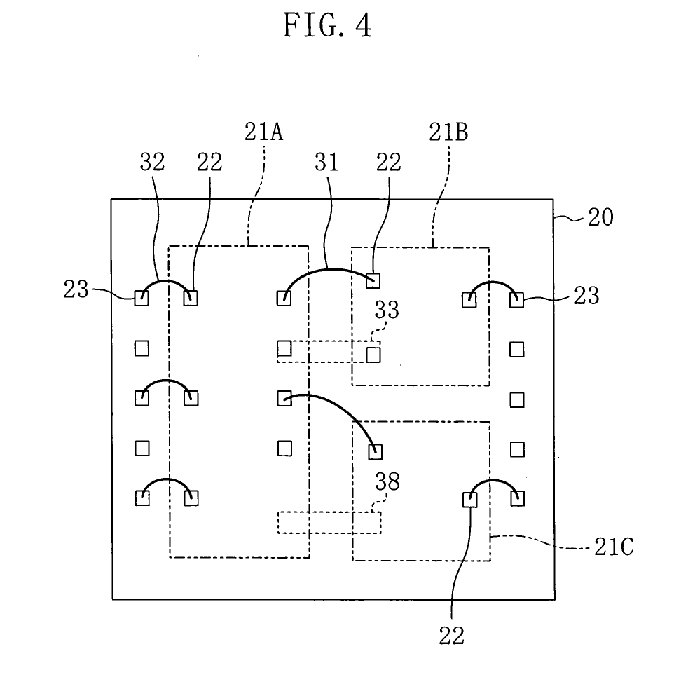

It is noted that if a part to be cut can be identified by pads therearound or a guide pattern or the like, which will be described later, the pads may be connected by means of not only the layer interconnect 33 but also an inter-block layer interconnect 38 for directly interconnecting the input/output terminals provided in the functional blocks with no pads interposed, as shown in FIG. 4.

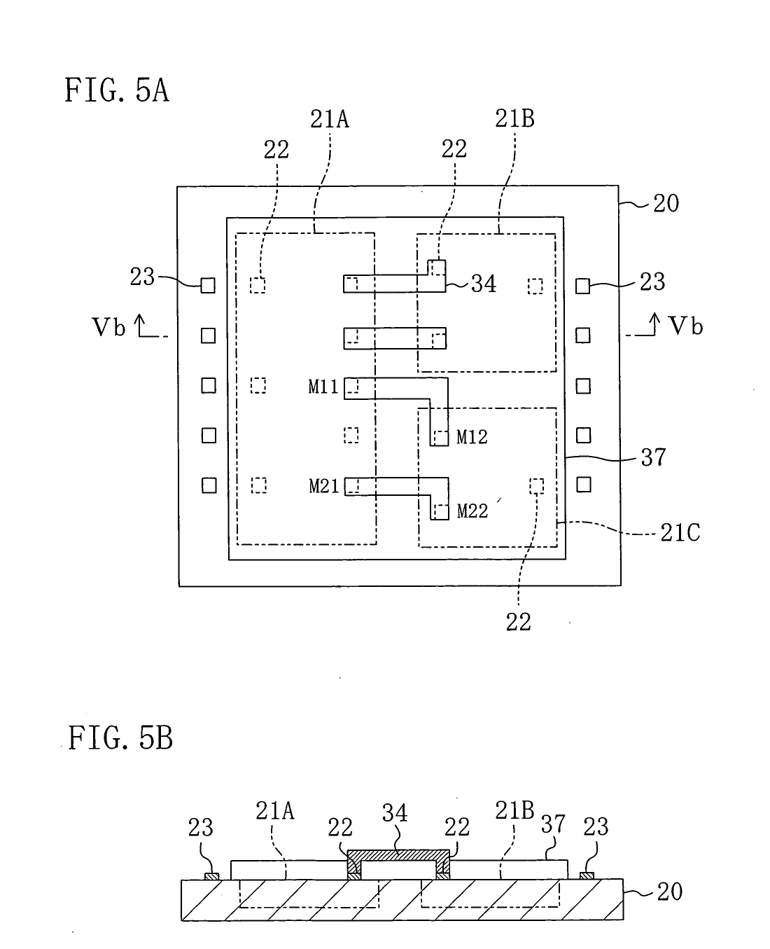

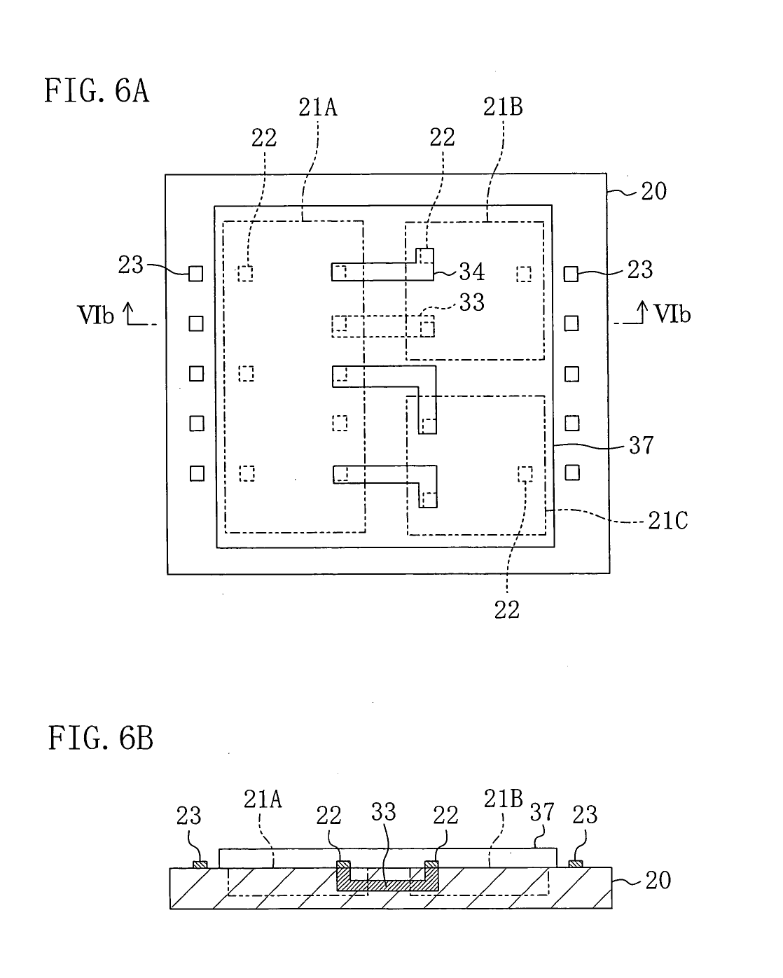

Moreover, a plated interconnect 34 may be formed by forming a plated substrate 37 on the semiconductor substrate as shown in FIG. 5, or the layer interconnect 33 may be employed in combination with the plated interconnect 34, as shown in FIG. 6. In either case employing, as the inter-pad interconnects, the plated interconnects or combination of the layer interconnect and the plated interconnect, the functional blocks can be separated or recombined easily.

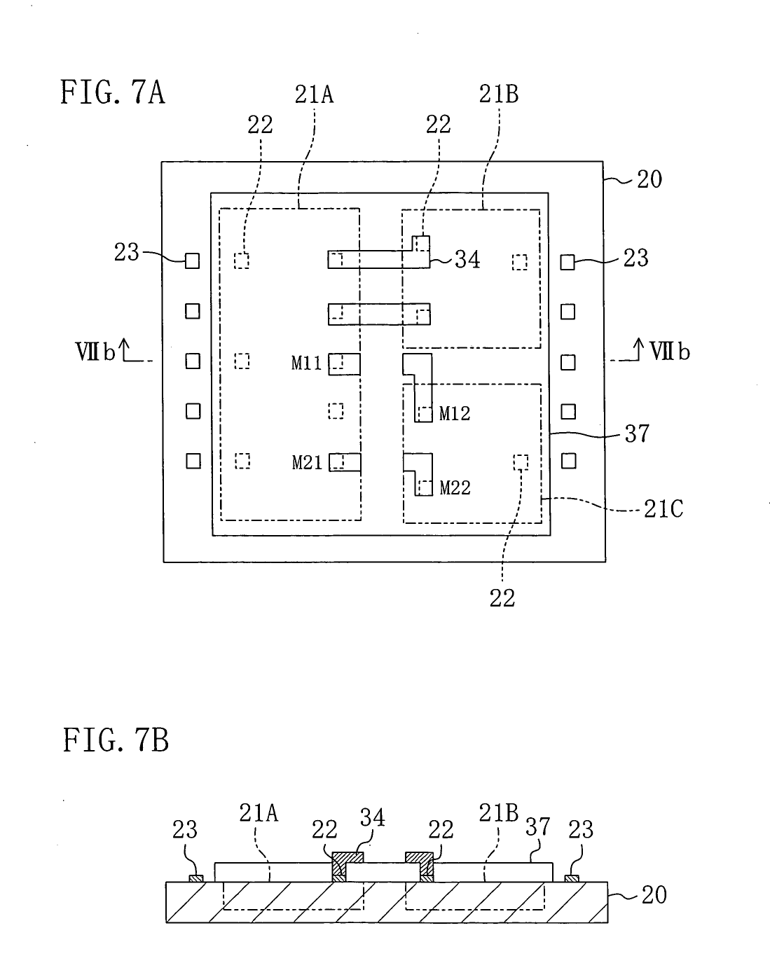

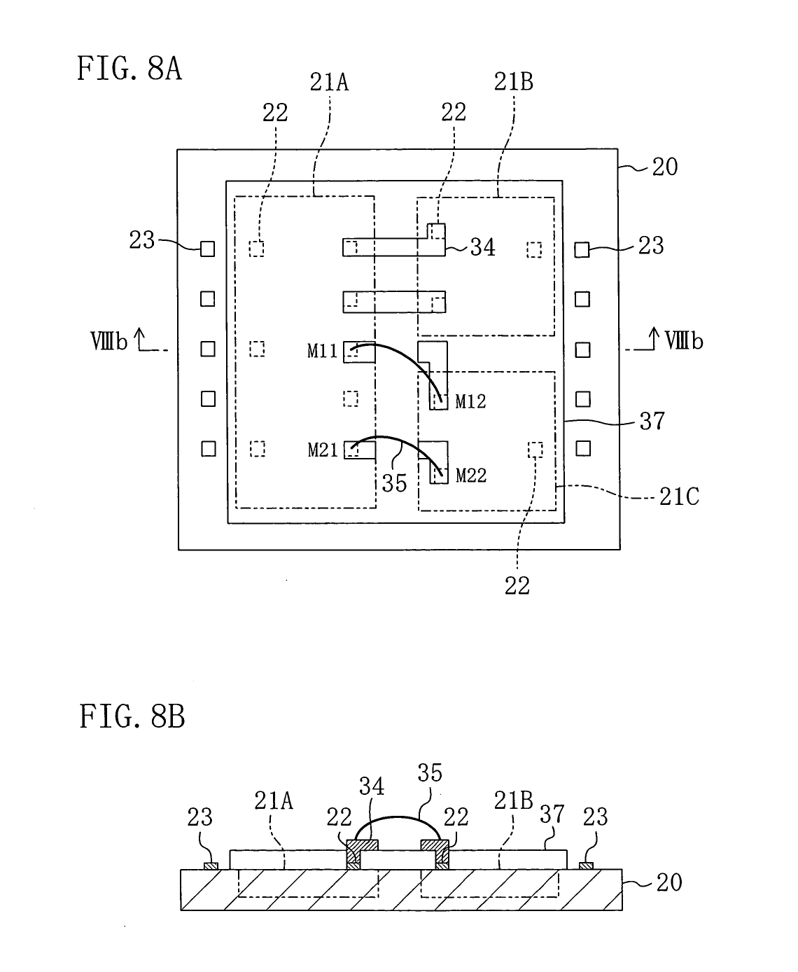

For example, in the case where pads M11 and M12 are connected and pads M21 and M22 are connected by means of plated interconnects as shown in FIG. 5, cutting between the pads M11 and M12 and between the pads M21 and M22 is easy as shown in FIG. 7. Further, a plated interconnect once cut can be connected again by a plated interconnect, or can be re-connected by means of the wire interconnect 35, as shown in FIG. 8. Change in connection of pads from the initial connection in re-connection results in recombination of functional blocks.

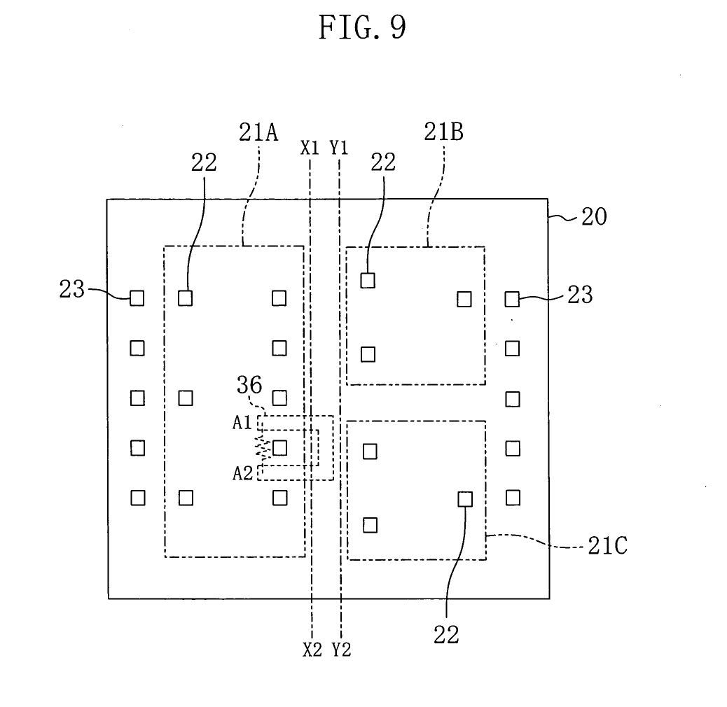

Some of the inter-pad interconnects may be used as an optional interconnect for changing the functions of a functional block. For example, in the case where a terminal A1 and a terminal A2 shown in FIG. 9 are connected with a resistor at 10 ohm interposed while the terminals A1 and A2 are connected by means of the layer interconnect 36 as an optional interconnect, the resistor does not work. While, when the base semiconductor chip 20 is cut along the line X1-X2 to cut the layer interconnect 36, the resistor at 10 ohm connected between the terminals A1 and A2 works. Thus, the functions of the functional blocks can be exchanged between connection and disconnection of the optional interconnect. Provision of a plurality of optional interconnects can change a plurality of functions. It is noted that the optional interconnect is not necessarily connected through the pads only if a part to be cut can be defined. The layer interconnect is used as the optional interconnect in FIG. 9, but the same effects can be attained by using the wire interconnect or the plated interconnect.

In addition, the semiconductor integrated circuit device is manufactured by forming the interconnects capable of being cut on the base semiconductor chip in the present embodiment, but an equivalent semiconductor integrated circuit device can be obtained by forming the inter-pad interconnects in a semiconductor chip as a part of the base semiconductor chip cut out therefrom. As well, the part thereof can be cut out after forming the inter-pad interconnects on the base semiconductor chip.

### Embodiment 2

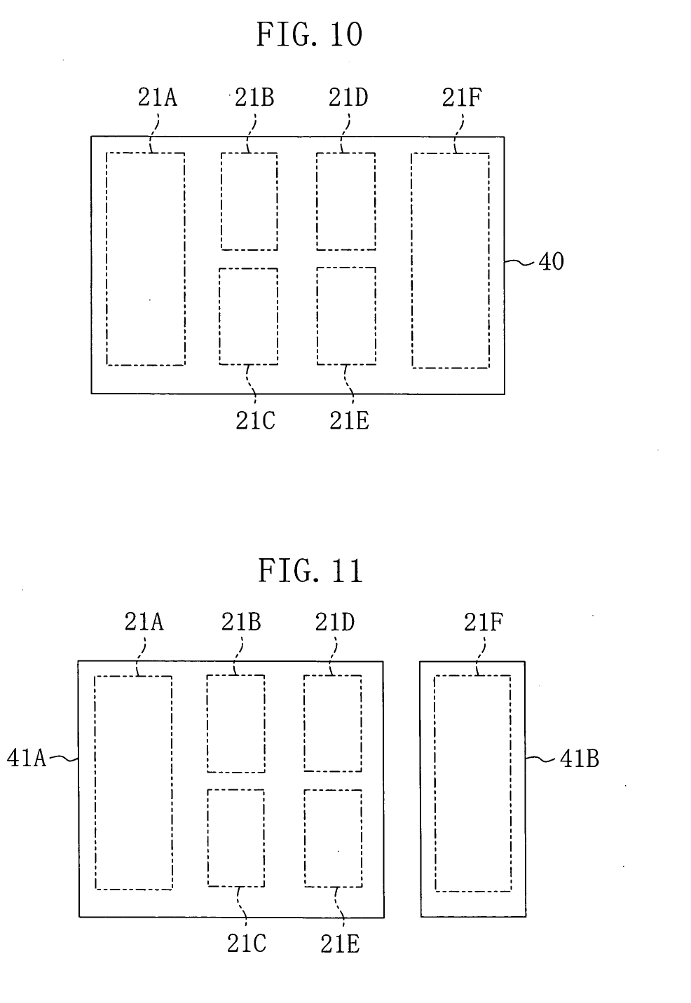

Embodiment 2 of the present invention will be described below with reference to the drawings. FIG. 10 shows a base semiconductor chip 40 according to Embodiment 2. In Embodiment 2, a part including a necessary functional block is cut out from the base semiconductor chip to form an LSI circuit including the necessary function.

As shown in FIG. 10, the base semiconductor chip 40 is composed of a plurality of functional blocks formed in a semiconductor substrate. The base semiconductor chip 40 shown in FIG. 10 includes six functional blocks of a first functional block 21A, a second functional block 21B, a third functional block 21C, a fourth functional block 21D, a fifth functional block 21E, and a sixth functional block 21F, for example.

Though not shown, a plurality of functional block pads 22 are formed along the peripheries of the functional blocks, similarly to those in FIG. 1. Accordingly, each region of the base semiconductor chip 40 where the functional blocks are formed can be identified easily. The functional block is formed so as to be operated independently, so that a region where an unnecessary functional block is formed can be removed physically as needed by cutting the base semiconductor chip 40.

A layer interconnect may be formed for interconnecting functional blocks. In the base semiconductor chip 40 of the present invention, the functional block pads are provided in each functional block, facilitating identification of the boundary between functional blocks. Accordingly, even with the layer interconnect formed for interconnecting the functional blocks, only a necessary functional block can be cut out. All interconnects may be formed of the layer interconnects so that the base semiconductor chip 40 exhibits a given function. In the case where all the functions of the functional blocks formed in the base semiconductor chip 40 are necessary, the base semiconductor chip 40 can be used as it is. Alternatively, only an interconnect which would not be cut may be formed of a layer interconnect while an interconnect which would be cut or subjected to frequent recombination is formed with the pad interposed after a specification of the semiconductor chip is determined. The layer interconnect may be the inter-pad interconnect for connecting pads or the inter-block layer interconnects for directly connecting input/output terminals provided in the function blocks with no pads interposed.

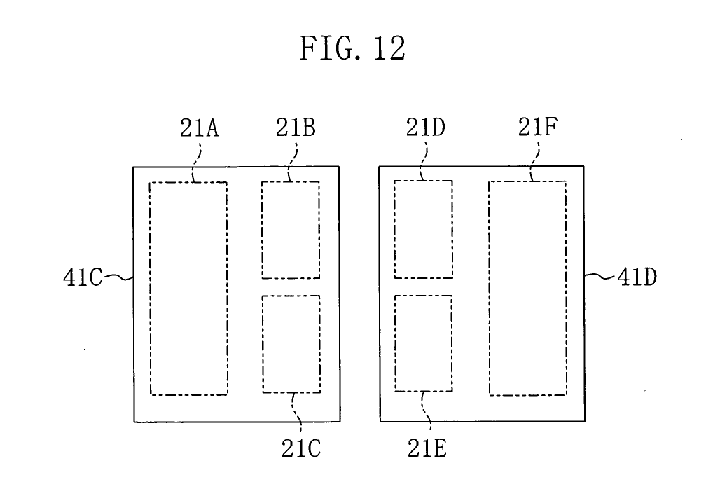

For example, the base semiconductor chip 40 can be divided easily into a semiconductor chip 41A in which the first to fifth functional blocks 21A to 21E are formed and a semiconductor chip 41B in which the sixth functional block 21F is formed, as shown in FIG. 11, or into a semiconductor chip 41C in which the first to third functional blocks 21A to 21C are formed and a semiconductor chip 41D in which the fourth to sixth functional blocks 21D to 21F are formed, as shown in FIG. 12.

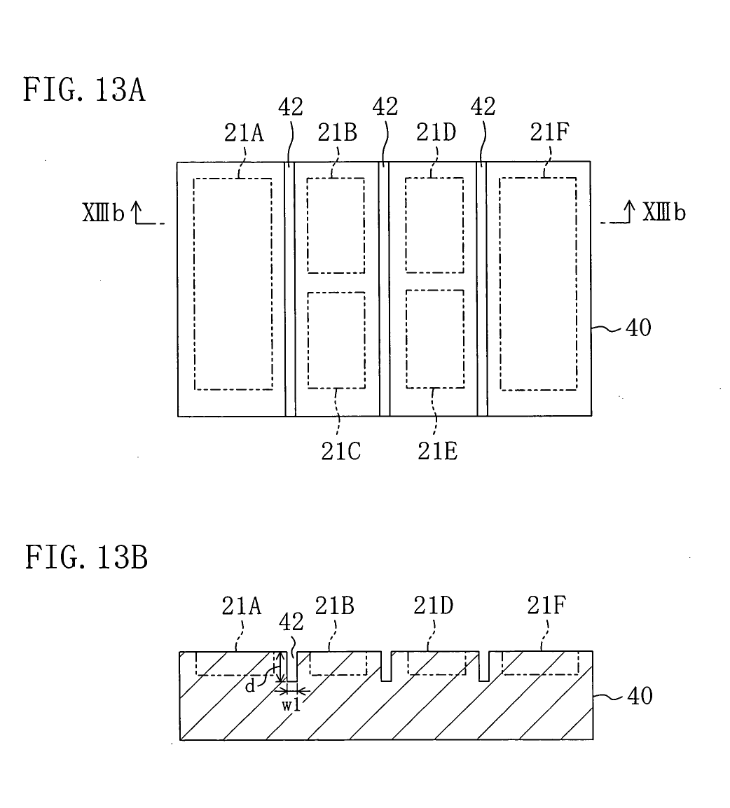

As shown in FIG. 13, trenches 42 may be formed along the boundaries between the functional blocks in the base semiconductor chip 40. The width w and the depth d of the trenches 42 may be set arbitrarily with the chip size and the like taken into consideration. Wherein, when the width w1 and the depth d of the trenches 42 are set to 50 μm and 100 μm, respectively, the boundaries of the functional blocks can be recognized to enable easy physical separation of the functional blocks.

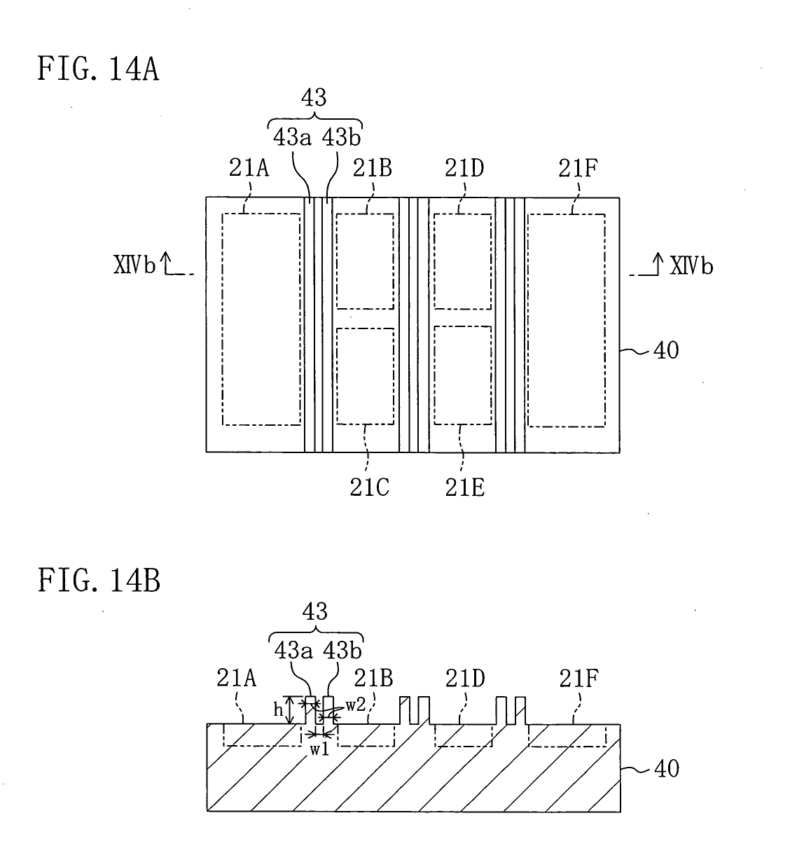

Alternatively, as shown in FIG. 14, a protrusion pair 43 may be formed rather than the trenches. In FIG. 14A, two protrusions 43a and 43b of the protrusion pair 43 are formed in parallel with each other along the boundary of functional blocks. When the width w2 and the height h of the paired protrusions 43a and 43b are set to 50 μm and 100 μm, respectively, and the distance w1 between the paired protrusions 43a, 43b is set to 50 μm, the boundary of the functional blocks can be recognized sufficiently so that the functional blocks can be separated selectively. Further, contamination of the functional blocks by cutting can be prevented in selective division and separation of the functional blocks.

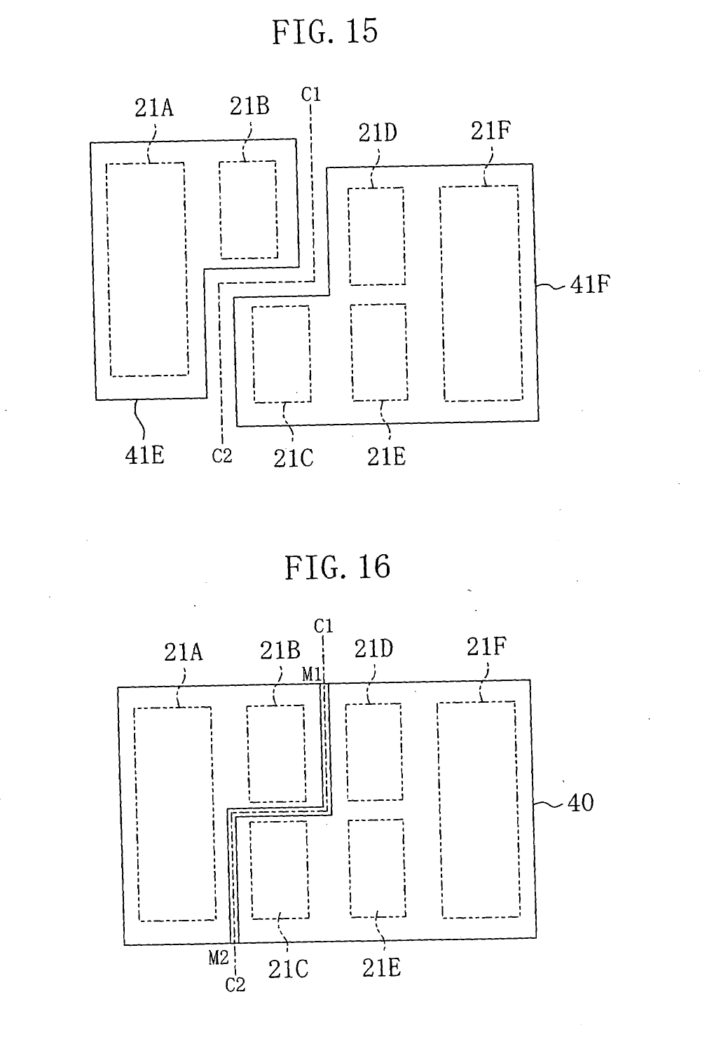

It should be noted that the base semiconductor chip 40 may not be divided into quadrangles. For example, the base semiconductor chip 40 may be divided, as shown in FIG. 15, into a semiconductor chip 41E in which the first and second functional blocks 21A and 21B are formed and a semiconductor chip 41F in which the third to sixth functional blocks 21C to 21F are formed. Division of the semiconductor chip into polygons, rather than quadrangles increases variation of the semiconductor chips. In recent years, semiconductor chips can be diced by a laser beam in lieu to a conventional diamond cutter. Dicing by the laser beam attains polygonal semiconductor chips.

For division into polygons as above, a guide line M1-M2 may be rendered along the boundary between functional blocks of the semiconductor chip 40, as shown in FIG. 16. The guide line may be rendered on the surface of the base semiconductor chip 40, on the semiconductor substrate itself of the base semiconductor chip 40, or on an insulating layer or the like formed on the semiconductor substrate. The guide line enables recognition of the boundary of the functional blocks, leading to easy and accurate cutting for separating the functional blocks along the boundary C1-C2.

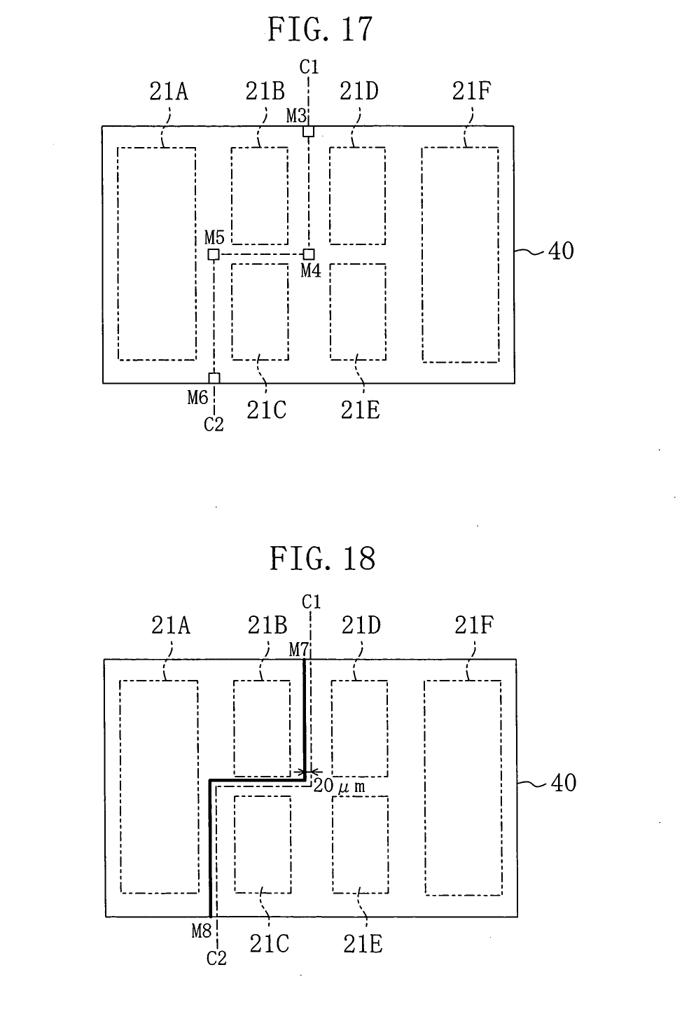

Alternatively, as shown in FIG. 17, guide patterns M3, M4, M5, and M6 may be provided at points to be apexes of a cutting line on the boundary of the functional bocks of the base semiconductor chip 40. The guide patterns may be formed on the surface of the base semiconductor chip 40 or be buried under the insulating layer or the like. Provision of the guide patterns on the boundary leads to easy and accurate cutting for separating the functional blocks along the boundary C1-C2 with contamination of the cut face suppressed to a minimum. Only a minimum number of guide patterns are provided for indicating reference points for dicing, which reduces cost at pattern formation.

Further, as shown in FIG. 18, a boundary pattern M7-M8 may be formed in the vicinity of the boundary of the functional blocks of the base semiconductor chip 40. The boundary pattern M7-M8 indicates that a part 20 μm right therefrom should be cut. The boundary pattern may be formed on the surface of the base semiconductor chip 40, on the semiconductor substrate itself of the base semiconductor chip 40, or on the insulating layer, or the like formed on the semiconductor substrate. Provision of the boundary pattern in the vicinity of the boundary leads to easy cutting for separation of the functional blocks with contamination of the cut face by the pattern suppressed. If the boundary pattern is formed just on a part to be diced, the boundary pattern obstructs dicing to worsen processing accuracy. In contrast, when the boundary pattern is formed slightly apart from the part to be cut, the base semiconductor chip 40 is free from the influence thereof, leading to accurate cutting. It is noted that the distance between the part to be diced and the boundary pattern is set to be 20 μm in the present embodiment, but the value thereof may changed appropriately.

Each semiconductor chip into which the base semiconductor chip 40 is divided may be used as a unit semiconductor chip. Further, when the functional blocks are interconnected by means of the inter-pad interconnect, such as the wire interconnect, the plated interconnect, or the like, an LSI circuit in which the functional blocks work as a whole can be attained. Hence, an LSI circuit can be formed by combining necessary functional blocks out of the functional blocks once formed in a base semiconductor chip, achieving efficient reducibility. In the case where all the functional blocks formed in the base semiconductor chip 40 are used, the functional bocks may be interconnected by means of the inter-pad interconnects without dividing the base semiconductor chip.

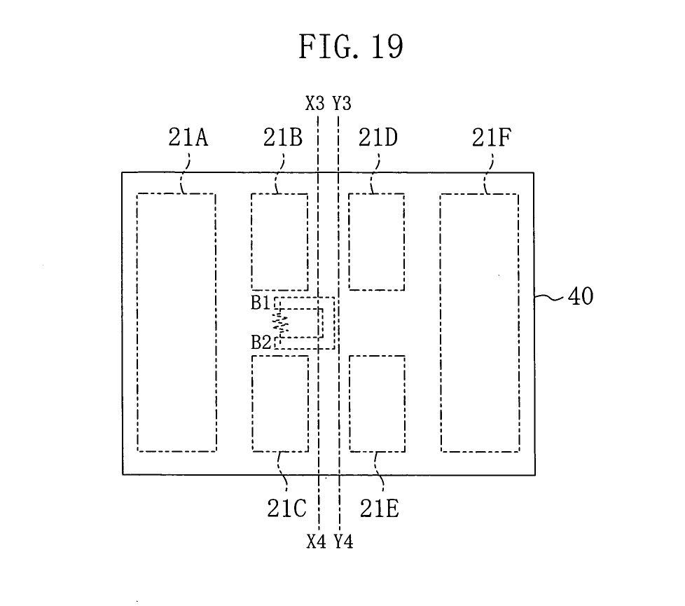

Moreover, when an optional interconnect is provided between functional blocks and is cut according to a necessary function, plural functions can be achieved as needed. For example, in FIG. 19, a terminal B1 and a terminal B2 are connected with a resistor at 10 ohm interposed while the terminals B1 and B2 are connected by means of the layer interconnect 36 as an optional interconnect. In this case, the resistor does not work. While, when the base semiconductor chip 40 is cut along the line X3 and X4, the resistor at 10 ohm connected between the terminals B1 and B2 works. In this way, provision of the optional interconnect achieves plural functions. Similarly, provision of an additional optional interconnect capable of being cut by cutting the base semiconductor chip 40 along the line Y3-Y4 achieves a further larger number of combinations. The optional interconnects are formed of layer interconnects in FIG. 19, but the same effects can be achieved by providing the wire interconnects or the plated interconnects as the optional interconnects. Further, the layer interconnect 36 may be an inter-pad interconnect for connecting the pads or an interconnect for connecting terminals with no pads interposed.

As described above, the semiconductor integrated circuit device and the base semiconductor chip according to the present invention enable easy identification of each functional block in the semiconductor substrate, selective division of the functional blocks, and flexible recombination of the functional blocks. Hence, the present invention is useful for a base semiconductor chip including a semiconductor substrate in which a plurality of functional blocks are formed, a semiconductor integrated circuit device using the base semiconductor chip, and a method for manufacturing the semiconductor integrated circuit device.

What is claimed is:

1. A semiconductor integrated circuit device, comprising:
a semiconductor substrate;
a semiconductor chip including a plurality of functional blocks formed independently from each other in predetermined regions of the semiconductor substrate and each including a pad for transmiting a signal; and
a plurality of inter-pad interconnects being connected to the pads and being capable of being cut,
wherein signal transmission between the respective functional blocks is performed through the respective inter-pad interconnects.

2. The semiconductor integrated circuit device of claim 1,
wherein the plurality of inter-pad interconnects include at least one of a wire interconnect, a plated interconnect, and a layer interconnect, or include any combination of the three.

3. The semiconductor integrated circuit device of claim 1, further comprising:
an inter-block layer interconnect for interconnecting functional blocks directly, the inter-block layer interconnect being used for signal transmission between the interconnected functional blocks.

4. The semiconductor integrated circuit device of claim 1,
wherein some of the plurality of functional blocks serves as a test functional block for testing an operation of at least one of the other functional blocks, and
an inter-pad interconnect connected to a pad of the test functional block is cut at the middle thereof.

5. The semiconductor integrated circuit device of claim 1,
wherein some of the plurality of functional blocks is a surplus functional block which is not required to be operated, and
the plurality of inter-pad interconnects are not connected to a pad formed at the surplus functional block out of the pads.

6. The semiconductor integrated circuit device of claim 1,
wherein some of the plurality of functional blocks is a surplus functional block which is not required to be operated, and
an inter-pad interconnect connected to a pad formed at the surplus functional block out of the pads is cut in the middle thereof.

7. The semiconductor integrated circuit device of claim 1,
wherein the semiconductor substrate is in a polygonal shape in plan.

8. A base semiconductor chip, comprising: a semiconductor substrate; and a plurality of functional blocks formed independently from each other in predetermined regions of the semiconductor substrate,
wherein each of the functional blocks includes a pad for transmitting a signal.

9. The base semiconductor chip of claim 8,
wherein a part of the semiconductor substrate where a region in which at least one functional block is formed is cut out functions as an independent semiconductor chip.

10. The base semiconductor chip of claim 8,
wherein the semiconductor chip is in a polygonal shape in plan.

11. The base semiconductor chip of claim 8, further comprising:
an optional interconnect formed in a region between functional blocks of the semiconductor substrate for exchanging a function of a functional block by being cut.

12. The base semiconductor chip of claim 8,
wherein a trench is formed in a boundary portion between functional blocks of the semiconductor substrate.

13. The base semiconductor chip of claim 8,
wherein a protrusion is formed along a boundary between functional blocks of the semiconductor substrate.

14. The base semiconductor chip of claim 8,
wherein in a boundary potion between functional blocks of the semiconductor substrate, a guide pattern serving as a reference indicating the boundary portion is provided.

15. The base semiconductor chip of claim 14,
wherein the guide pattern is a guide line rendered along a boundary.

16. The base semiconductor chip of claim 14,
wherein the guide pattern is provided a part slightly apart from a boundary between the functional blocks.

17. A semiconductor integrated circuit device manufacturing method, comprising the steps of:
(a) preparing a base semiconductor chip, which is a semiconductor substrate in which a plurality of functional blocks each having a pad are formed independently from each other;
(b) selectively combining the plurality of functional blocks by forming a plurality of inter-pad interconnects which connect corresponding pads out of the pads of the functional blocks and which are capable of being cut; and
(c) separating some of the plurality of functional blocks by cutting some of the plurality of inter-pad interconnects.

18. The semiconductor integrated circuit device manufacturing method of claim 17,
wherein the plurality of inter-pad interconnects formed in the step (b) include at least one of a wire interconnect, a plated interconnect, and a layer interconnect, or include any combination of the three.

19. The semiconductor integrated circuit device manufacturing method of claim 17, further comprising a step (d) of testing, using some of the plurality of functional blocks, an operation of at least one of the other functional blocks before the step (c) and after the step (b),
wherein the functional block used for the test is separated in the step (c).

20. The semiconductor integrated circuit device manufacturing method of claim 17,
wherein some of the plurality of functional blocks is a surplus functional block which is not required to be operated, and
the surplus functional block is separated in the step (c).

21. The semiconductor integrated circuit device manufacturing method of claim 17, further comprising a step (e) of changing, after the step (c), a combination of the plurality of functional blocks by forming another wire interconnect or a plated interconnect.

22. The semiconductor integrated circuit device manufacturing method of claim 17, further comprising a step (f) of separating, after the step (a), a region of the semiconductor substrate where some of the plurality of functional blocks is formed from a region thereof where the other functional block is formed by dicing.

23. The semiconductor integrated circuit device manufacturing method of claim 22,
wherein at least one of the separated semiconductor substrates has a polygonal shape in plan.
